(19) United States
(12) Patent Application Publication
(10) Pub. No.: US 2013/0050001 A1
(43) Pub. Date: Feb. 28, 2013

(54) CALIBRATION SCHEME FOR ANALOG-TO-DIGITAL CONVERTER

(71) Applicants: Oystein Moldsvor, Tiller (NO); Bjornar Hernes, Trondheim (NO); Ivar Lokken, Tiller (NO)

(72) Inventors: Oystein Moldsvor, Tiller (NO); Bjornar Hernes, Trondheim (NO); Ivar Lokken, Tiller (NO)

(73) Assignee: Hittite Microwave Norway AS, Tiller (NO)

(21) Appl. No.: 13/504,685

(22) PCT Filed: Aug. 24, 2010
(86) PCT No.: PCT/IB10/02267

§ 371 Date: Aug. 6, 2012

Related U.S. Application Data
(60) Provisional application No. 61/256,130, filed on Oct. 29, 2009.

(51) Int. Cl. H03M 1/10

(52) U.S. Cl. 341/120

(57) ABSTRACT

An analog-to-digital converter (ADC) apparatus comprising an input signal connector, an output signal port, two or more sub-ADCs, a digital signal processing (DSP) block, wherein the result from each sub-ADC is used by the DSP block to output data with increased performance and perform calibration of each sub-ADC independently while the other sub-ADCs and the DSP block operate and output data normally.

This application claims priority to U.S. Provisional Application Ser. No. 61/256,130 filed on Oct. 29, 2009.

### BACKGROUND

1. Technical Field

The present disclosure generally relates to analog-to-digital conversion techniques, and more particularly, to a calibration scheme for analog-to-digital conversion.

2. Description of the Related Art

Several electronic systems require analog-to-digital converters (ADCs) for their function. Depending on the characteristics of a particular system, there are specific requirements to the ADC and the performance parameters of the ADC. Increased performance, in terms of accuracy, resolution and linearity, comes at a cost of increased power dissipation due to the basic laws of physics. In addition, developments in the digital signal processing realm and the rapid increase in computational power made available by deep sub-micron chip manufacturing technologies, has made obtainable accuracy, speed and performance in the digital domain virtually infinite. This results in an increasing demand for high performance and speed in their analog counterparts where ADCs in most systems represent the bottleneck.

The limits for accuracy and speed associated with ADCs have continuously improved. However, at a certain stage, the performance that can be obtained in analog circuitry is limited by the lack of adequate accuracy in the technology used for the manufacturing the circuits.

The effects of limited accuracy and mismatch errors in the manufacturing technology can be mitigated by several techniques like trimming, averaging and various forms of calibration. However, trimming is an effective, but rather costly process. Therefore, it is used only in systems where performance is absolutely required and the increased cost can be tolerated.

Averaging is a simple methodology and has the additional benefit of reducing random noise. Averaging also improves the signal-to-noise ratio (SNR) of the ADC in addition to mitigating problems related to the limited accuracy and mismatch errors caused by the manufacturing technology employed. For instance, the prior art averaging technique of FIG. 1 may be employed to reduce the effects of mismatch and to improve the total SNR in an ADC. More specifically, an input 104 is applied to an arbitrary number of sub-ADCs 100-102 which can be configured in parallel such that each sub-ADC 100-102 represents an ADC channel, or simply channel. The sub-ADCs 100-102 can be completely separate ADCs or any combination of multi-channel ADCs. Each ADC samples the signal at the input 104 and converts it to a digital word with a given accuracy. The digital output data from each sub-ADC is collected by a digital signal processing block 103 and presented at an output 105 in a suitable format for further processing. The digital signal processing block 103 calculates the average of the data provided by each sub-ADC 100-102. Calculating the average is equivalent to summing the outputs of the sub-ADC 100-102, and if desired, truncating the output to a suitable number of bits.

Assuming that the random noise is uncorrelated in each of the sub-ADCs 100-102, the equivalent output noise is reduced by a factor of 3 dB each time the number of sub-ADCs 100-102 is doubled. Denoting the SNR of a single sub-ADC 100-102 as SNR_{sub-ADC}, the total SNR at the output 105, SNRₜₒₜₐₗ, becomes

SNRₜₒₜₐₗ=SNR_{subADC} 10 log₁₀ N_{subADC}, (1)

wherein N_{sub-ADC} equals the number of sub-ADCs 100-102 that are used. The mismatch errors will follow the same equation as random noise assuming that the errors are uncorrelated between each sub-ADC 100-102. In many cases the errors cannot be guaranteed to be uncorrelated between the channels. Calibration may be required in such situations. In addition, calibration may remove errors much more efficiently than what is obtainable with averaging.

There are two different approaches to the calibration of ADCs, including foreground calibration and background calibration.

Background calibration is done concurrently with normal operation of the ADC. There are several prior art techniques implementing background calibration. In most cases, the calibration is performed by adding a known calibration signal to the signal propagating through the ADC. This calibration signal is subtracted from the ADC output to ensure that the performance of the ADC is not degraded. Advanced signal processing algorithms are used to analyze properties of the calibration signal while passing through the circuitry, and based on the results, to adjust coefficients used to compensate for different types of errors or inaccuracies in the circuit.

All solutions for background calibration presented to date have at least two major issues. The first is high complexity and a very tight coupling between the analog performance and the digital calibration logic. This results in a very complex and hard to manage design process. The other major limitation is the long convergence time required in the calibration algorithms. In most publications, several tens of millions of ADC conversions are reported as the required convergence time of the calibration signal. Even for high speed ADCs, this results in a convergence time that is too long to track typical variation in parameters that could arise from variations in temperature or supply voltage.

There exist both analog and digital solutions for foreground calibration. Common to these techniques is that the ADC is required to cease normal operation, perform a calibration sequence employing the same circuitry as is used during normal operation, then return back to normal operation. For many electronic systems it is acceptable that the ADC is unavailable for normal operation at certain points in time. However, in many applications, the ADC is running continuously, and will have to be calibrated without interruption of normal operation. This is often solved by having redundant circuitry that can be used when a calibration sequence is performed. The extra cost and complexity of such solutions make the use impractical, and seldom applied in commercial products.

### SUMMARY OF THE DISCLOSURE

In satisfaction of the aforenoted needs, an analog-to-digital converter (ADC) with increased performance is disclosed. The ADC comprises several sub-ADCs, a signal input, a digital signal processing (DSP) block and a digital output. Each sub-ADC converts the input signal with a given accuracy and transfers the output to the DSP block. The average of the results from each sub-ADC is calculated to output a single digital output word with higher signal-to-noise ratio (SNR). Each sub-ADC separately has means to disconnect from the input, perform a calibration sequence, and then resume normal operations. During calibration of a particular sub-ADC, the remaining sub-ADCs will operate normally with a slightly reduced SNR since the number sub-ADCs used for averaging is smaller.

Another ADC apparatus configured to output data with increased performance is disclosed. The ADC apparatus comprises an input signal connector, an output signal port, two or more sub-ADCs and a DSP block. The DSP block is configured to receive the output of each sub-ADC, and further, configured to perform calibration of each sub-ADC independently while the other sub-ADCs and the DSP block are configured to operate and output data normally.

In a refinement, an analog input signal is passed through separate blocks prior to being applied at the input of each sub-ADC.

Yet another ADC configured to output data with increased performance is disclosed. The ADC comprises an input signal connector, an output signal port, two or more sub-ADCs, a DSP block and a control mechanism. The DSP block is configured to receive the output of each sub-ADC, and further, configured to perform calibration of each sub-ADC independently while the other sub-ADCs and the DSP block are configured to operate and output data normally. The control mechanism is configured to sequence the calibration of each channel and, during operation, configured to continuously maintain optimum performance of all sub-ADCs and the DSP block.

In a refinement, an analog input signal is passed through separate blocks prior to being applied at the input of each sub-ADC.

Other advantages and features will be apparent from the following detailed description when read in conjunction with the attached drawings.

### BRIEF DESCRIPTION OF THE DRAWINGS

The disclosed analog-to-digital converter (ADC) apparatus is described more or less diagrammatically in the accompanying drawings wherein:

FIG. 1 is a prior art schematic of an ADC apparatus; and

FIG. 2 is a schematic of an exemplary ADC apparatus that is constructed in accordance to the teachings of the disclosure.

It should be understood that the drawings are not necessarily to scale and that the embodiments are sometimes illustrated by graphic symbols, phantom lines, diagrammatic representations and fragmentary views. In certain instances, details which are not necessary for an understanding of this disclosure or which render other details difficult to perceive may have been omitted. It should be understood, of course, that this disclosure is not limited to the particular embodiments and methods illustrated herein.

### DETAILED DESCRIPTION OF THE DISCLOSURE

The principle of operation of the disclosure is based on averaging of multiple analog-to-digital converter (ADC) channels in order to increase accuracy and at the same time allow calibration of each channel without interrupting normal operations.

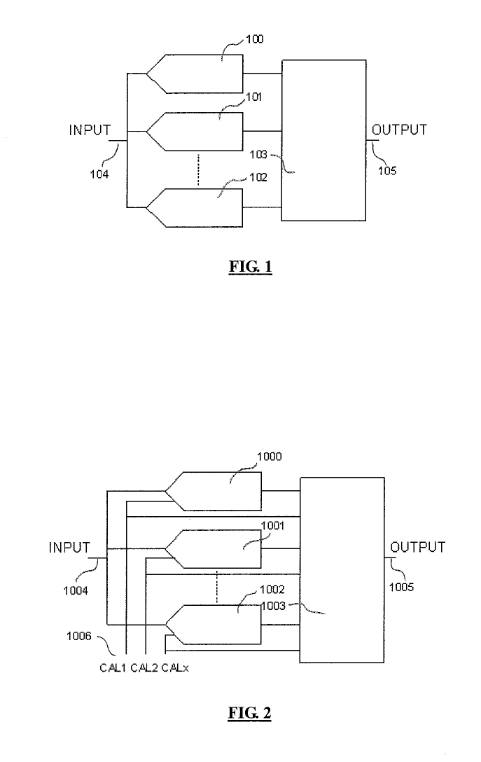

The embodiment of FIG. 1 illustrates a prior art solution in which accuracy may be improved by employing an averaging configuration or technique. The exemplary embodiment of FIG. 2 illustrates an ADC configuration in which averaging may be employed to increase the signal-to-noise ratio (SNR) and allow calibration to be run without interruption of normal ADC operations. More specifically, the input signal 1004 may be applied to an arbitrary number of sub-ADCs 1000-1002 configured in parallel, wherein each sub-ADC 1000-1002 represents a channel. The sub-ADCs 1000-1002 may be completely separate ADCs 1000-1002 or any combination of multi-channel ADCs 1000-1002. Each ADC 1000-1002 may sample the signal at the input 1004 and convert it to a digital word with a given accuracy. The digital output data may be collected by a digital signal processing (DSP) block 1003 and output at, for instance, an output port 1005 in a suitable format for further processing.

The DSP 1003 may be configured to calculate the average of the data from each sub-ADC 1000-1002. Calculating the average may be equivalent to summing all outputs of the sub-ADCs 1000-1002, and if desired, truncating the output to a suitable number of bits. The resulting SNR from the ADC apparatus may be determined by, for instance, equation (1).

Each sub-ADC 1000-1002 may further provide a calibration input 1006. For example, when the calibration input 1006 for one channel is activated, the channels may disconnect from the input 1004, perform a calibration sequence and connect back to the input 1004 to resume normal operations. The calibration scheme for each ADC channel may be implemented in any way suitable for the architecture used in each sub-ADC 1000-1002.

During calibration of one channel, the remaining channels may operate as normal. In this period, the resulting SNR may be slightly reduced depending on the total number of sub-ADCs 1000-1002 in the system. For instance, equation (2) illustrates the resulting SNR during calibration, SNR_{CAL}, wherein N_{sub-ADC} may correspond to the number of sub-ADCs 1000-1002 and M_{CAL} may correspond to the number of sub-ADCs 1000-1002 in calibration.

SNR_{CAL}=SNR_{subADC} 10 log₁₀ N_{subADC}−M_{CAL} (2)

As can be seen from equation (2), the number of sub-ADCs 1000-1002 calibrated at the same time, M_{CAL}, may be one.

One can also see from equation (2) that the SNR during calibration can be made almost equal to the SNR in normal operations by having a higher number of sub-ADCs 1000-1002. Most applications, however, may require the SNR to be suitable in average over a certain number of samples. This may allow the use of a lower number of sub-ADCs 1000-1002 if used in conjunction with the following method.

Several ADC samples may be required to perform a full calibration for most ADC calibration schemes. However, the samples do not need to be consecutive. This may allow the calibration samples to be spread over a longer time period.

For example, if M_{N} samples are performed with all sub-ADCs 1000-1002 operating in a normal operating mode, then M_{CAL} sub-ADCs 1000-1002 may perform one single calibration sample followed by a new sequence of M_{N} samples with normal operations. Subsequently, the second sub-ADC 1000-1002 performs one calibration followed by a new sequence of M_{N} samples with normal operations. Such a sequence may be repeated until all channels have performed the required number of calibration samples, M_{C}, each. The average SNR, SNR_{AVG}, and the calibration period, T_{CAL}, may be determined as shown in equation (3). The calibration period may be a measure of how fast the calibration feature is able to track changes in conditions that typically arise due to varying environmental conditions. For instance, power supply voltage and temperature, T_{CAL}, may be measured in number of clock cycles.

$${SNR}_{AVG} = {SNR}_{subADC} 10 {log}_{10} \frac{{N}_{subADC} {M}_{N} 1 - {M}_{CAL}}{{M}_{N} 1} \\ {T}_{CAL} = {M}_{N} 1 {M}_{C} \frac{{N}_{subADC}}{{M}_{CAL}} \qquad ( 3 )$$

In the event there are four channels, wherein each channel requires 32 samples for calibration, and wherein every 16th sample is a calibration sample, M_{N}=15, the loss in SNR compared with four channels without calibration is only 0.05 dB. The calibration time will be 2048 samples which is several decades lower than that exhibited by prior art calibration solutions.

While only certain embodiments have been set forth, alternatives and modifications will be apparent from the above description to those skilled in the art. These and other alternatives are considered equivalents and within the spirit and scope of this disclosure and the appended claims.

What is claimed:

1. An analog-to-digital converter (ADC) apparatus configured to output data with increased performance, comprising:
an input signal connector;
an output signal port;
two or more sub-ADCs, each sub-ADC having an output; and
a digital signal processing (DSP) block configured to receive the output of each sub-ADC, the DSP being configured to perform calibration of each sub-ADC independently while the other sub-ADCs and the DSP block are configured to operate and output data normally.

2. The apparatus of claim 1, wherein an analog input signal is passed through separate blocks prior to being applied at the input of each sub-ADC.

3. An analog-to-digital converter (ADC) configured to output data with increased performance, comprising:
an input signal connector;
an output signal port;
two or more sub-ADCs, each sub-ADC having an output;
a digital signal processing (DSP) block configured to receive the output of each sub-ADC, the DSP being configured to perform calibration of each sub-ADC independently while the other sub-ADCs and the DSP block are configured to operate and output data normally; and
a control mechanism configured to sequence the calibration of each channel and, during operation, configured to continuously maintain optimum performance of all sub-ADCs and the DSP block.

4. The apparatus of claim 3, wherein an analog input signal is passed through separate blocks prior to being applied at the input of each sub-ADC.
